(19) United States
(12) Patent Application Publication
(10) Pub. No.: US 2010/0070141 A1
(43) Pub. Date: Mar. 18, 2010

(54) Electronic apparatus

(75) Inventors: Tatsuki Tanaka, Nagoya-city (JP); Makoto Sakai, Kariya-city (JP); Takashi Inamoto, Nagoya-city (JP)

Correspondence Address: HARNESS, DICKEY & PIERCE, P.L.C., P.O. BOX 828, BLOOMFIELD HILLS, MI, 48303, US

(73) Assignee: DENSO CORPORATION, Kariya-city (JP)

(21) Appl. No.: 12/584,983

(22) Filed: Sep. 15, 2009

(30) Foreign Application Priority Data
Sep. 16, 2008 (JP) 2008-236907
Sep. 26, 2008 (JP) 2008-248060

(51) Int. Cl. B60R 21/01; H03H 7/01

(52) U.S. Cl. 701/45; 333/181

(57) ABSTRACT

An electronic apparatus includes an integrated circuit, a capacitor, and first and second wires. The integrated circuit has a terminal connected to a power supply line or a signal line. The capacitor eliminates noise on the power supply line or the signal line. The first wire connects a first end of the capacitor to the terminal of the integrated circuit. The second wire connects a second end of the capacitor to a reference potential. A length of the first wire is substantially equal to a length of the second wire.

### CROSS REFERENCE TO RELATED APPLICATION

This application is based on and incorporates herein by reference Japanese Patent Application No. 2008-236907 filed on Sep. 16, 2008 and No. 2008-248060 filed on Sep. 26, 2008.

### FIELD OF THE INVENTION

The present invention relates to an electronic apparatus having a capacitor for eliminating noise on a power supply line or a signal line connected to an integrated circuit.

### BACKGROUND OF THE INVENTION

In recent years, there have been an increased number of vehicles equipped with an airbag apparatus for protecting occupants in a crash. For example, an airbag apparatus disclosed in U.S. Pat. No. 7,539,804 corresponding to JP-A-2007-215102 includes an airbag electronic control unit (ECU) as a master node, multiple sensors as slave nodes, and an airbag. The airbag EUC is located approximately in the center of a vehicle. The sensors are located on front and side portions of the vehicle and connected to the airbag ECU through communication buses.

In addition to an airbag apparatus, various electronic components are mounted on a vehicle. There is a possibility that such an electronic component may produce noise and also external disturbance noise may affect the airbag apparatus. Therefore, the airbag apparatus has a capacitor for eliminating noise. Specifically, the capacitor is added to a power supply unit and between communication buses.

For another example, in a differential communication apparatus disclosed in JP-A-2003-46655, a master node and a slave node are connected together through a pair of wires. The master node and the slave node communicate with each other, and the master node feeds power to the slave node.

In a differential communication, a balanced cable such as a twisted pair cable is used. Therefore, a differential communication has high resistance to noise compared to a single-ended communication. Moreover, in the differential communication apparatus disclosed in JP-A-2003-46655, a capacitor and a choke coil are used to reduce common mode noise. For further another example, in an apparatus disclosed in US 2007/0262788 corresponding to JP-A-2007-267363, an impedance of a slave node is adjusted to a predetermined value to reduce common mode noise.

However, such noise may not be fully eliminated depending on a layout pattern of a printed circuit board and a positional relationship between each node and a capacitor. Therefore, it is difficult to improve a resistance to noise.

### SUMMARY OF THE INVENTION

In view of the above, it is an object of the present invention to provide an electronic apparatus having a structure for improving a resistance to noise.

According to a first aspect of the present invention, an electronic apparatus includes an integrated circuit, a capacitor, and first and second wires. The integrated circuit has a terminal connected to a power supply line or a signal line. The capacitor has first and second ends and is configured to eliminate noise on the power supply line or the signal line. The first wire has a first length and connects the first end of the capacitor to the terminal of the integrated circuit. The second wire has a second length and connects the second end of the capacitor to a reference potential. The first length is substantially equal to the second length.

According to a second aspect of the present invention, a differential communication apparatus includes a master integrated circuit, a slave integrated circuit, a sensor device, and a capacitive element. The slave integrated circuit is connected to the master integrated circuit through a pair of communication lines to perform differential communication with the master integrated circuit. The slave integrated circuit includes a power supply circuit fed with a first voltage from the master integrated circuit through the pair of communication lines. The sensor device is connected to the power supply circuit through a power supply line and a ground line and fed with a second voltage from the slave integrated circuit. The sensor device is configured to output a third voltage depending on the second voltage to the slave integrated circuit. The sensor device is a separate piece of the slave integrated circuit. The capacitive element is connected between the power supply line and the ground line. Each of the power supply line and the ground line includes a first section connecting an output terminal of the slave integrated circuit to an input terminal of the sensor device, a second section connecting an output terminal of the power supply circuit to the output terminal of the slave integrated circuit, and a third section connecting a terminal of the capacitive element to the output, terminal of the slave integrated circuit. An impedance of the power supply line is substantially equal to an impedance of the ground line in at least one of the first, second, and third sections.

According to a third aspect of the present invention, a differential communication apparatus includes a master integrated circuit, a slave integrated circuit, and a capacitive element. The slave integrated circuit includes an input/output circuit connected to the master integrated circuit through a pair of communication lines to perform differential communication with the master integrated circuit, a power supply circuit fed with a first voltage from the master integrated circuit through the input/output circuit, and a sensor device connected to the power supply circuit through a power supply line and a ground line and fed with a second voltage from the power supply circuit. The sensor device is configured to output a third voltage depending on the second voltage to the input/output circuit. The capacitive element is connected between the power supply line and the ground line. Each of the power supply line and the ground line includes a first section connecting an output terminal of the power supply circuit to an input terminal of the sensor device, and a second section connecting a terminal of the capacitive element to the output terminal of the power supply circuit. An impedance of the power supply line is substantially equal to an impedance of the ground line in at least one of the first and second sections.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a top view of a vehicle equipped with an airbag apparatus according to a first embodiment of the present invention;

FIG. 2 is a block diagram illustrating the airbag apparatus;

FIG. 3 is a schematic diagram illustrating a slave sensor of the airbag apparatus;

FIG. 4 is a graph illustrating waveforms of voltages of a communication bus of the airbag apparatus;

FIG. 5 is a block diagram illustrating a control apparatus according to a second embodiment of the present invention;

FIG. 6 is a block diagram illustrating a slave node of the control apparatus;

FIG. 7 is a graph illustrating waveforms of voltages of terminals of the slave node; and

FIG. 8 is a block diagram illustrating a control apparatus according to a third embodiment of the present invention.

### DETAILED DESCRIPTION OF THE PREFERRED EMBODIMENTS

### First Embodiment

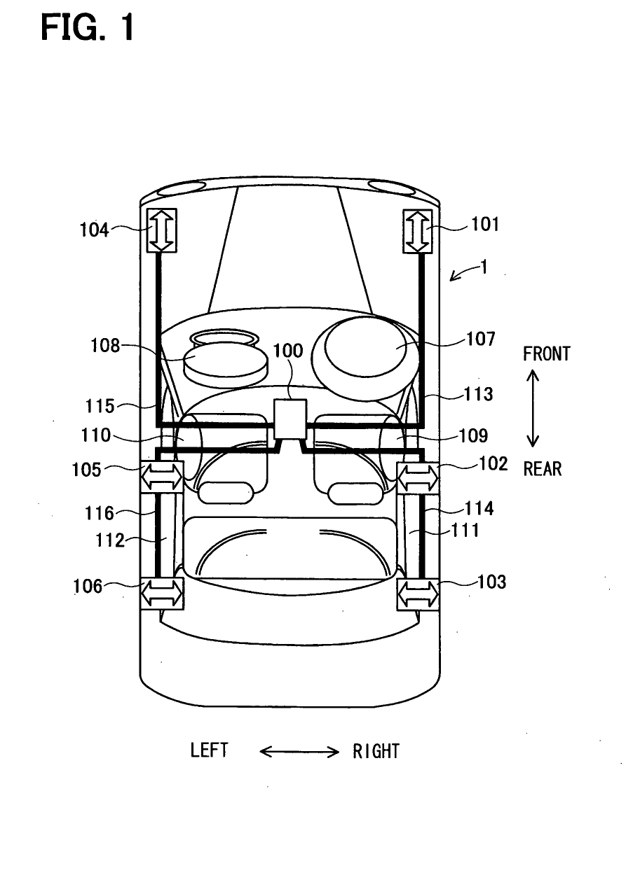

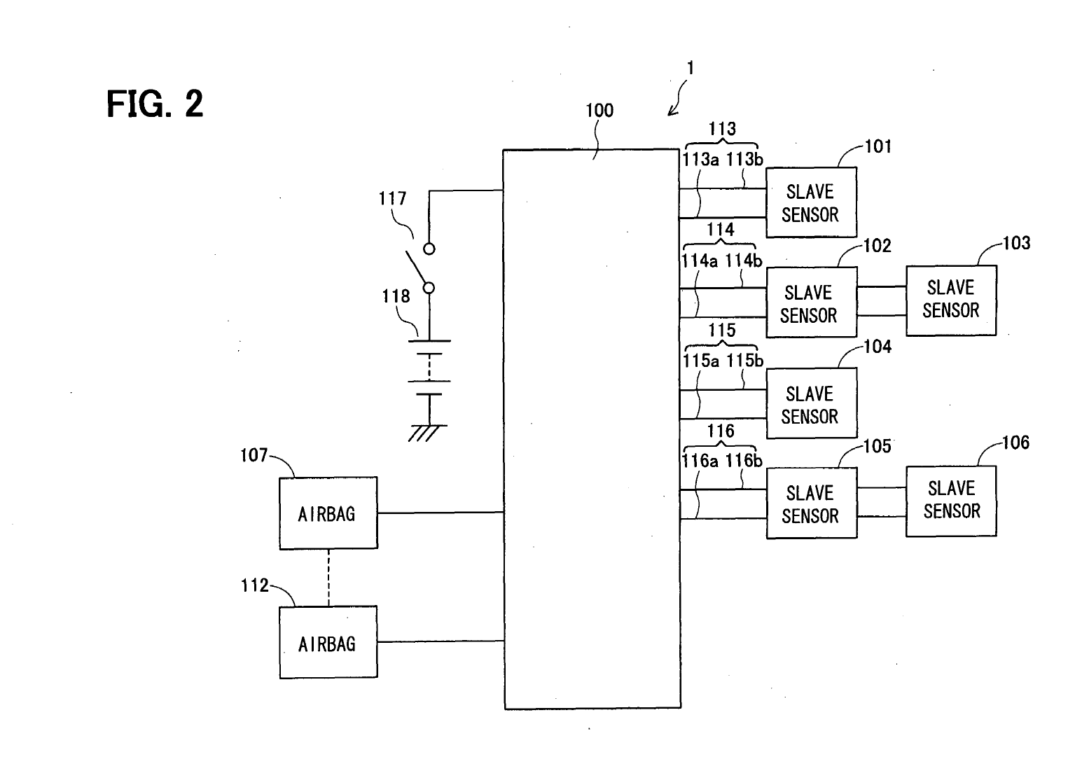

An airbag apparatus 1 according to a first embodiment of the present invention is described below with reference to FIGS. 1, 2. As shown in FIGS. 1, 2, the airbag apparatus 1 includes an airbag ECU 100, slave sensors 101-106 as an electronic apparatus, a driver-side front airbag 107, a passenger-side front airbag 108, side airbags 109, 110, and curtain airbags 111, 112.

The airbag ECU 100 has a built-in acceleration sensor (not shown). The airbag ECU 100 deploys the driver-side front airbag 107, the passenger-side front airbag 108, the side airbags 109, 110, and the curtain airbags 111, 112 based on acceleration detected by the built-in acceleration sensor and accelerations detected by the slave sensors 101-106. The airbag ECU 100 is located approximately in the center of a vehicle.

The slave sensors 101-106 detect accelerations of various parts of the vehicle. In response to data request commands from the airbag ECU 100, the slave sensors 101-106 send the detected accelerations to the airbag ECU 100 through communication buses 113-116.

As shown in FIG. 1, the slave sensor 101 is located on a front right side of the vehicle and detects a front-rear direction acceleration of the vehicle. The slave sensor 102 is located near a C-pillar on a right side of the vehicle and detects a left-right direction acceleration of the vehicle. The slave sensor 103 is located near a B-pillar on the right side of the vehicle and detects the left-right direction acceleration of the vehicle. As shown in FIG. 2, the slave sensor 101 is connected to the airbag ECU 100 through a reference line 113a and a transmission line 113b of the communication bus 113. The slave sensors 102, 103 are connected to the airbag ECU 100 through a reference line 114a and a transmission line 114b of the communication bus 114.

As shown in FIG. 1, the slave sensor 104 is located on a front left side of the vehicle and detects the front-rear direction acceleration of the vehicle. The slave sensor 105 is located near a C-pillar on a left side of the vehicle and detects the left-right direction acceleration of the vehicle. The slave sensor 106 is located near a B-pillar on the left side of the vehicle and detects the left-right direction acceleration of the vehicle. As shown in FIG. 2, the slave sensor 104 is connected to the airbag ECU 100 through a reference line 115a and a transmission line 115b of the communication bus 115. The slave sensors 105, 106 are connected to the airbag ECU 100 through a reference line 116a and a transmission line 116b of the communication bus 116.

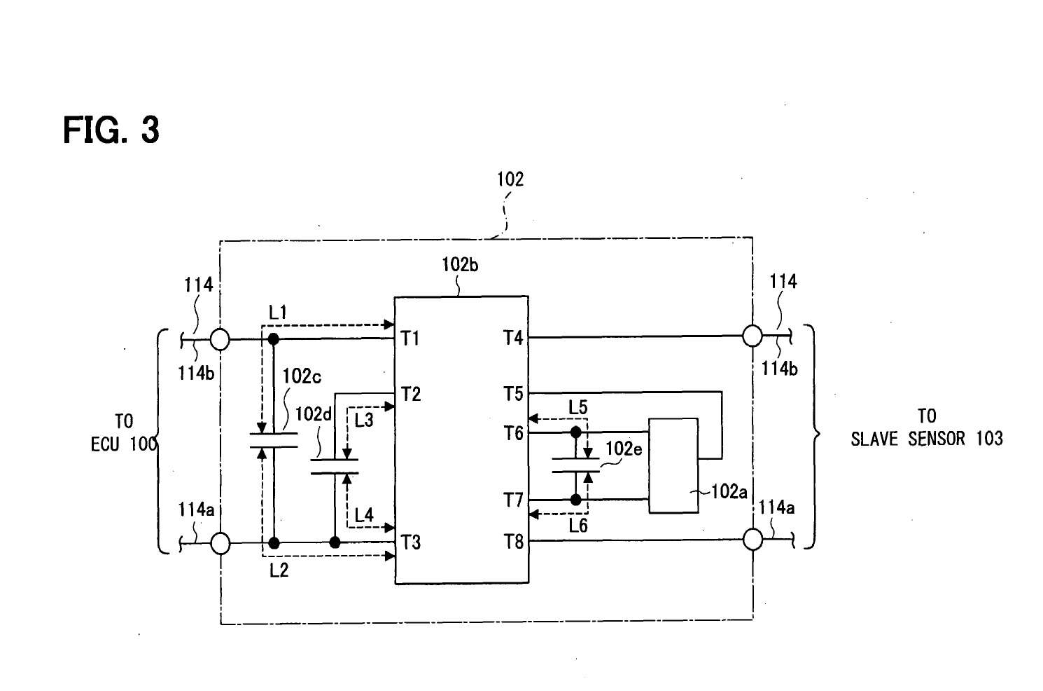

The slave sensors 101-106 are described in detail with reference to FIG. 3. The slave sensors 101-106 are identical in configuration. Therefore, as an example, the slave sensor 102 is described below. It is noted that a subsequent stage side of the slave sensor 102 is connected to the slave sensor 103.

As shown in FIG. 3, the slave sensor 102 includes a sensor device 102a, a communication integrated circuit (IC) 102b, and capacitors 102c, 102d, and 102e.

The sensor device 102a has a power supply terminal and an analog signal output terminal, each of which is connected to the communication IC 102b. The sensor device 102a is activated by a direct current (DC) voltage. The DC voltage is fed to the sensor device 102a from the communication IC 102b through the power supply terminal. The sensor device 102a detects the acceleration of the vehicle and outputs an analog signal indicative of the detected acceleration to the communication IC 102b through the analog signal output terminal.

The communication IC 102b is activated by a DC voltage. The DC voltage is fed to the communication IC 102b from the airbag ECU 100 through the communication bus 114. In response to the data request command from the airbag ECU 100, the communication IC 102b converts the analog signal received from the sensor device 102a into acceleration data and sends the acceleration data to the airbag ECU 100. Further, the communication IC 102b converts the DC voltage received from the airbag ECU 100 into a drive voltage (as a DC voltage) suitable to activate the sensor device 102a and feeds the drive voltage to the sensor device 102a.

The communication IC 102b has terminals T1-T8. The terminals T1, T2 of the communication IC 102b are connected through the communication bus 114 to the airbag ECU 100. The terminals T4, T8 of the communication IC 102b are connected through the communication bus 114 to the slave sensor 103. The terminals T6, T7 of the communication IC 102b are connected to the power supply terminal of the sensor device 102a. The terminal T5 is connected to the analog signal output terminal, of the sensor device 102a.

The capacitor 102c eliminates noise on the communication bus 114. Specifically, the capacitor 102c eliminates noise induced in the DC voltage, the data request command, and the acceleration data that are transmitted through the communication bus 114. A first end of the capacitor 102c is connected to the terminal T1 (as a first terminal) of the communication IC 102b. The terminal T1 of the communication IC 102b is connected to the transmission line 114b that serves as a power supply line and a signal line. A second end of the capacitor 102c is connected to the terminal T3 (as a second terminal) of the communication IC 102b. The terminal T3 of the communication IC 102b is connected to the reference line 114a that serves as a reference potential. It is noted that a length L1 of a wire from the first end of the capacitor 102c to the terminal T1 is substantially equal to a length L2 of a wire from the second end of the capacitor 102c to the terminal T3.

The capacitor 102d is charged by the DC voltage that is received from the airbag ECU 100 to drive the communication IC 102b. Further, the capacitor 102d eliminates noise induced in the DC voltage. A first end of the capacitor 102d is connected to the terminal T2 (as a first terminal) of the communication IC 102b. A power supply line for feeding the DC voltage to the communication IC 102b is internally connected to the terminal T2 of the communication IC 102b. A second end of the capacitor 102d is connected to the terminal T3 of the communication IC 102b. The terminals T2, T3 are arranged adjacent to each other. It is noted that a length L3 of a wire from the first end of the capacitor 102d to the terminal T2 is substantially equal to a length L4 of a wire from the second end of the capacitor 102d to the terminal T3.

The capacitor 102e eliminates noise induced in the drive voltage that is received from the communication IC 102b to drive the sensor device 102a. A first end of the capacitor 102e is connected to the terminal T6 (as a first terminal) of the communication IC 102b. A power supply line for feeding the drive voltage to the sensor device 102a is internally connected to the terminal T6 of the communication IC 102b. A second end of the capacitor 102e is connected to the terminal T7 (as a second terminal) of the communication IC 102b. The terminals T6, T7 are arranged adjacent to each other. Further, a reference line serving as a reference potential of the drive voltage is internally connected to the terminal T7 of the communication IC 102b. It is noted that a length L5 of a wire from the first end of the capacitor 102e to the terminal T6 is substantially equal to a length L6 of a wire from the second end of the capacitor 102e to the terminal T7.

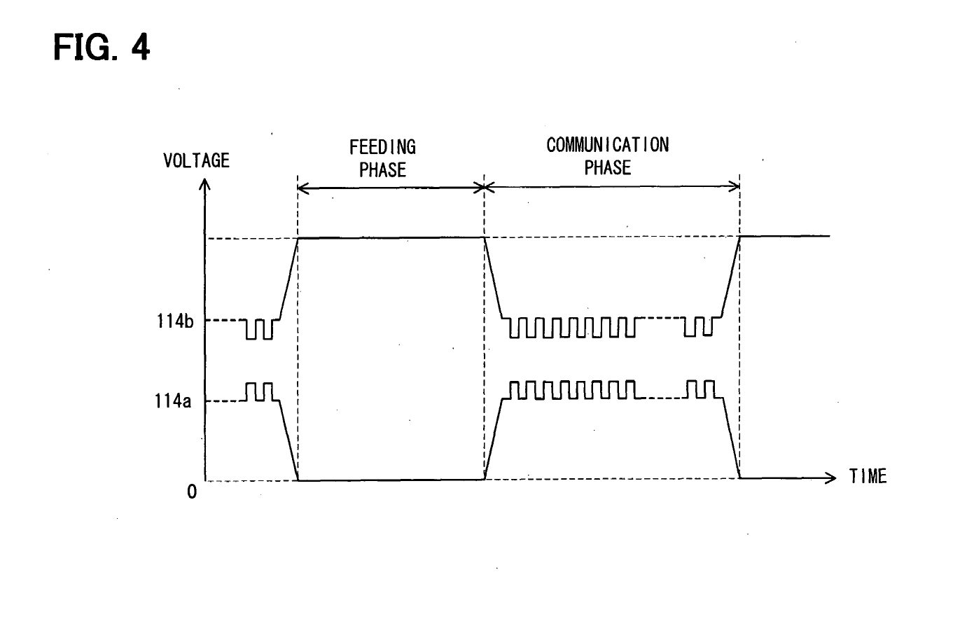

Operations of the airbag apparatus 1 are described below with reference to FIGS. 2-4. FIG. 4 is a graph illustrating waveforms of voltages of the reference line 114a and the transmission line 114b of the communication bus 114.

In FIG. 2, when an ignition switch 117 is turned ON, a DC voltage of a battery 118 is applied to the airbag ECU 100 so that the airbag ECU 100 can start to operate. During a feeding phase shown in FIG. 4, the airbag ECU 100 feeds a DC voltage to the slave sensors 101-106 through the communication buses 113-116.

As shown in FIG. 4, the reference line 114a becomes a reference potential (e.g., vehicle body potential), and the transmission line 114b becomes a predetermined DC potential so as to serve as a power supply line. Thus, the slave sensor 102 is fed with a DC voltage through the communication bus 114. In the slave sensor 102, the capacitor 102d is charged by the DC voltage so that the communication IC 102b can start to operate. The communication IC 102b converts the DC voltage stored in the capacitor 102d into a drive voltage to drive the sensor device 102a and feeds the drive voltage to the sensor device 102a. The capacitor 102e is charged by the fed drive voltage so that the sensor device 102a can start to operate. Like the slave sensor 102, each of the slave sensors 101 and 103-106 is fed with a DC voltage and start to operate.

During a communication phase subsequent to the feeding phase, the airbag ECU 100 successively sends the data request command to the, slave sensors 101-106 through the communication buses 113-116.

In the slave sensor 102, as shown in FIG. 4, the data request command is serially sent by changing the voltages of the reference line 114a and the transmission line 114b. If the slave sensor 102 determines that the data request command is associated with the slave sensor 102, the slave sensor 102 converts acceleration detected by the sensor device 102a into acceleration data and serially sends the acceleration data to the airbag ECU 100 by changing the voltages of the reference line 114a and the transmission line 114b. Like the slave sensor 102, each of the slave sensors 101 and 103-106 serially sends acceleration data to the airbag ECU 100.

The airbag ECU 100 determines which of the driver-side front airbag 107, the passenger-side front airbag 108, the side airbags 109, 110, and the curtain airbags 111, 112 needs to be deployed based on the acceleration data sent from the slave sensors 101-106 and the acceleration detected by the built-in acceleration sensor. Then, the airbag ECU 100 deploys the airbags to protect occupants of the vehicle.

Typically, in addition to the airbag apparatus 1, various electronic components are mounted on the vehicle. Therefore, there is a possibility that such an electronic component may produce noise and also external disturbance noise may affect the airbag apparatus 1.

According to the first embodiment, the communication IC 102b is provided with the capacitor 102c for eliminating noise induced in the DC voltage, the data request command, and the acceleration data. The length L1 of the wire from the first end of the capacitor 102c to the terminal T1 of the communication IC 102b is substantially equal to the length L2 of the wire from the second end of the capacitor 102c to the terminal T3 of the communication IC 102b. In such an approach, a phase difference in common phase noise between the first and second ends of the capacitor 102c can be reduced.

Further, the communication IC 102b is provided with the capacitors 102d, 102e for eliminating noise and for storing the DC voltage. The length L3 of the wire from the first end of the capacitor 102d to the terminal T2 of the communication IC 102b is substantially equal to the length L4 of the wire from the second end of the capacitor 102d to the terminal T3 of the communication IC 102b. In such an approach, a phase difference in common phase noise between the first and second ends of the capacitor 102d can be reduced. Further, the length L5 of the wire from the first end of the capacitor 102e to the terminal T6 of the communication IC 102b is substantially equal to the length L6 of the wire from the second end of the capacitor 102e to the terminal T7 of the communication IC 102b. In such an approach, a phase difference in common phase noise between the first and second ends of the capacitor 102e can be reduced. Thus, a resistance to noise can be improved.

Specifically, the first ends of the capacitors 102c-102e are connected to the terminals T1, T2, T6, which are connected to the power supply line or the signal line. The second ends of the capacitors 102c-102e are connected to the terminals T3, T7, which are connected to the reference potential. Since the wires from the first ends of the capacitors 102c-102e to the terminals T1, T2, T6 are substantially equal to the wires from the second ends of the capacitors 102c-102e to the terminals T3, T7, the phase difference in common phase noise between the first and second ends of the capacitors 102c-102e can be reduced. Thus, the airbag apparatus 1 can have an improved resistance to noise.

Moreover, according to the first embodiment, the terminals T2, T3 are arranged adjacent to each other. In such an approach, the length L3 of the wire from the first end of the capacitor 102d to the terminal T2 and the length L4 of the wire from the second end of the capacitor 102d to the terminal T3 can be reduced. Likewise, the terminals T6, T7 are arranged adjacent to each other. In such an approach, the length L5 of the wire from the first end of the capacitor 102e to the terminal T6 and the length L6 of the wire from the second end of the capacitor 102e to the terminal T7 can be reduced. Accordingly, electric current loop area defined by the capacitors 102d, 102e and the wires are reduced so that the resistance to noise can be further improved.

### Second Embodiment

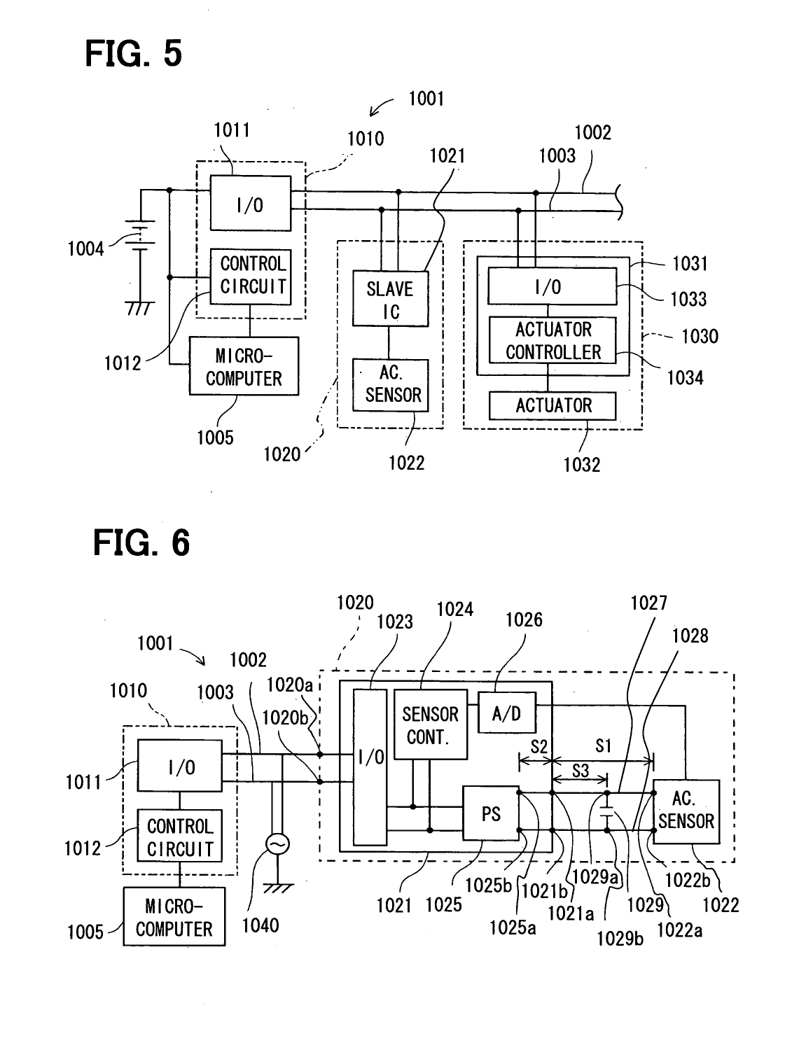

A control apparatus 1001 according to a second embodiment of the present invention is described below with reference to FIGS. 5, 6.

As shown in FIGS. 5, 6, the control apparatus 1001 mainly includes a pair of communication lines 1002, 1003, a battery 1004, a microcomputer 1005, a master node 1010, a slave node 1020, and a slave node 1030. The master node 1010 is connected through the pair of communication lines 1002, 1003 to the slave nodes 1020, 1030 so that the master node 1010 can perform differential communication with the slave nodes 1020, 1030. The battery 1004 feeds electrical power to the microcomputer 1005 and the master node 1010. The microcomputer 1005 is an electronic control unit (ECU) and communicates with the master node 1010 to control an occupant protection apparatus (not shown) or the like.

The master node 1010 (as a master IC) includes an input/output (I/O) circuit 1011 and a control circuit 1012. The control circuit 1012 is connected through the pair of communication lines 1002, 1003 and the I/O circuit 1011 to the slave nodes 1020, 1030 so that the control circuit 1012 can perform differential communication with the slave nodes 1020, 1030. Further, the control circuit 1012 feeds electrical power between the pair of communication lines 1002, 1003 through the I/O circuit 1011. The master node 1010 applies a voltage between the pair of communication lines 1002, 1003. The master node 1010 has a small output impedance to output a high voltage. Thus, the master node 1010 performs differential communication with the slave nodes 1020, 1030 through the pair of communication lines 1002, 1003. Specifically, the master node 1010 feeds electrical power to the slave nodes 1020, 1030, sends control signals to the slave nodes 1020, 1030, and receives output signals of the slave nodes 1020, 1030.

Each of the slave nodes 1020, 1030 detects transmission data from the master node 1010 by detecting a voltage between the pair of communication lines 1002, 1003 and sends a signal to the master node 1010 by changing an electric potential or a current value of the pair of communication lines 1002, 1003. In this way, the master node 1010 communicates with the slave nodes 1020, 1030 based on a pulsed voltage or current between the communication line 1002 of a higher potential and the communication line 1003 of a lower potential. In addition, the master node 1010 reduces an electrical potential of the communication line 1002 at a predetermined timing by limiting the electrical power fed to the communication line 1002, thereby forming a pulsed voltage between the pair of communication lines 1002, 1003 so that a command can be sent to a specific slave node.

The slave node 1020 includes a slave. IC 1021 and an acceleration sensor 1022. The slave IC 1021 feeds electrical power to the acceleration sensor 1022 based on a voltage inputted through the pair of communication lines 1002, 1003. Further, the slave IC 1021 sends an output signal of the acceleration sensor 1022 to the master node 1010. The acceleration sensor 1022 detects a change in speed of a vehicle, i.e., detects acceleration of the vehicle. The slave IC 1021 and the acceleration sensor 1022 are mounted on a common board.

The slave node 1030 includes a slave IC 1031 and an actuator 1032. The slave IC 1031 includes an I/O circuit 1033 and an actuator controller 1034. The actuator controller 1034 is configured as a microcomputer and receives a control signal from the master node 1010 through the pair of communication lines 1002, 1003 and the I/O circuit 1033. The actuator controller 1034 controls the actuator 1032 in accordance with the received control signal.

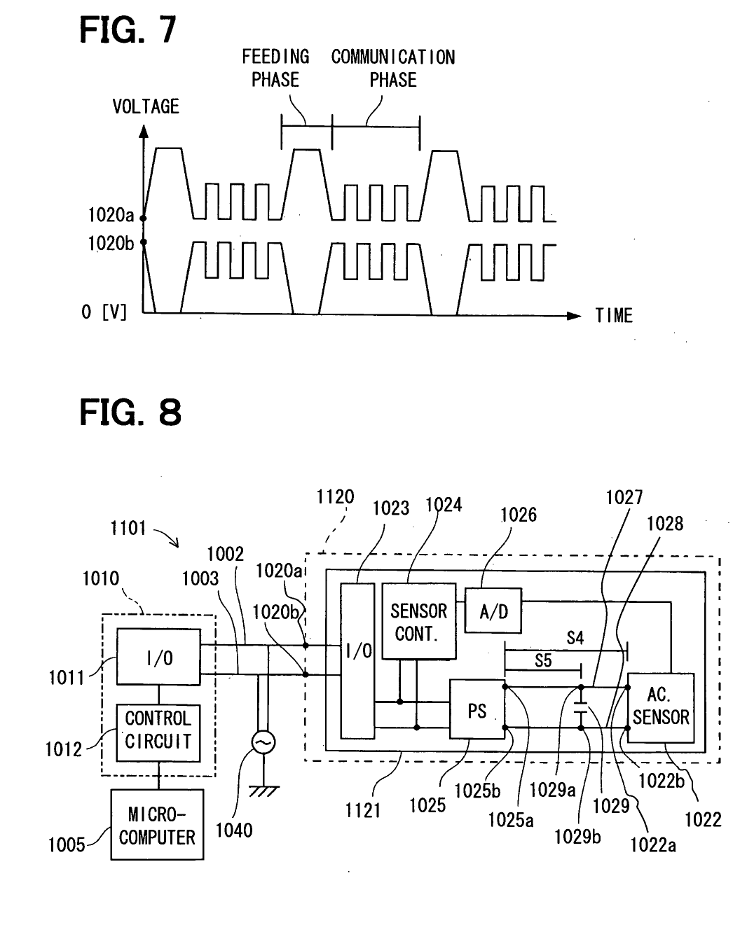

The slave node 1020 is described in detail below with reference to FIGS. 6, 7. FIG. 6 is a block diagram illustrating the slave node 1020, and FIG. 7 is a diagram illustrating waveforms of voltages of terminals 1020a, 1020b of the slave node 1020.

As mentioned previously, the slave node 1020 includes the slave IC 1021 and the acceleration sensor 1022. The slave IC 1021 includes an I/O circuit 1023, a sensor controller 1024, a power supply circuit 1025, and an analog-to-digital (ND) converter 1026.

The I/O circuit 1023 feeds the electrical power, which is received from the pair of communication lines 1002, 1003, to the sensor controller 1024 and the power supply circuit 1025. Although not shown in the drawings, the I/O circuit 1023 includes a battery circuit constructed with a capacitor and a diode. The capacitor is charged through the diode when an electrical potential of the communication line 1002 is greater than a threshold level, so that the capacitor can apply a DC voltage to the sensor controller 1024 and the power supply circuit 1025. A plus terminal of the capacitor is connected to the communication line 1002, and a minus terminal of the capacitor is connected to the communication line 1003. As mentioned previously, the communication line 1002 serves as a higher potential power supply line, and the communication line 1003 serves as a lower potential power supply line.

The master node 1010 performs differential communication with the slave nodes 1020, 1030 through the pair of communication lines 1002, 1003. For example, as shown in FIG. 7, the waveforms of the voltages of the terminals 1020a, 1020b of the slave node 1020 are different between in the feeding phase and in the communication phase. During the feeding phase, the master node 1010 feeds a DC voltage to the slave node 1020 through the pair of communication lines 1002, 1003 by using a vehicle body as a reference potential. During the communication phase, the master node 1010 and the slave node 1020 communicate with each other by pulsing the voltages of the pair of communication lines 1002, 1003 in opposite phases. Although the waveforms shown in FIG. 7 are waveforms of voltages of the terminals 1020a, 1020b of the slave node 1020, the waveforms shown in FIG. 7 are substantially equivalent to waveforms of voltages of input terminals of the I/O circuit 1023.

During the feeding phase, the power supply circuit 1025 of the slave node 1020 generates a drive voltage (as a DC voltage) from the DC voltage received through the pair of communication lines 1002, 1003 and stores the drive voltage. Then, the power supply circuit 1025 feeds the drive voltage to the acceleration sensor 1022. The sensor controller 1024 controls the power supply circuit 1025 so that the drive voltage outputted from the power supply circuit 1025 can be controlled to a target value.

The power supply circuit 1025 is connected to the acceleration sensor 1022 through a power supply line 1027 and a ground line 1028. The power supply line 1027 includes a plus on-board wire portion that connects a plus output terminal 1021a of the slave IC 1021 to a plus input terminal 1022a of the acceleration sensor 1022. The power supply line 1027 further includes a plus IC-internal wire portion that connects a plus output terminal 1025a of the power supply circuit 1025 to the plus output terminal 1021a of the slave IC 1021. Likewise, the ground line 1028 includes a minus on-board wire portion that connects a minus output terminal 1021b of the slave IC 1021 to a minus input terminal 1022b of the acceleration sensor 1022. The ground line 1028 further includes a minus IC-internal wire portion that connects a minus output terminal 1025b of the power supply circuit 1025 to the minus output terminal 1021b of the slave IC 1021. A capacitor 1029 is connected in parallel to the acceleration sensor 1022 in order to eliminate or reduce noise between the power supply circuit 1025 and the acceleration sensor 1022. A plus terminal 1029a of the capacitor 1029 is connected to the power supply line 1027, and a minus terminal 1029b of the capacitor 1029 is connected to the ground line 1028.

The acceleration sensor 1022 generates an output voltage by changing the drive voltage according to the detected acceleration and sends the output voltage to the ND converter 1026. For example, when the drive voltage received from the power supply circuit 1025 is 5V, and the detected acceleration is 0G, the acceleration sensor 1022 sends to the A/D converter 1026 the output voltage of 2.5V, which is half the drive voltage. For another example, when the detected acceleration is positive, the acceleration sensor 1022 sends the output voltage of 3.5V to the ND converter 1026 according to the detected acceleration. In is way, the output voltage of the acceleration sensor 1022 depends on not only the detected acceleration, but also the drive voltage received from the power supply circuit 1025.

The ND converter 1026 generates an output signal by ND-converting the output voltage of the acceleration sensor 1022 and sends the output signal to the sensor controller 1024. The sensor controller 1024 calculates acceleration detected by the acceleration sensor 1022 based on the output signal of the ND converter 1026 and the drive voltage outputted from the power supply circuit 1025 to the acceleration sensor 1022. As mentioned previously, the sensor controller 1024 controls the power supply circuit 1025 so that the drive voltage outputted from the power supply circuit 1025 can be controlled to a target value. The sensor controller 1024 outputs an acceleration signal indicative of the calculated acceleration to the pair of communication lines 1002, 1003 through the I/O circuit 1023.

According to a conventional structure, if the power supply circuit 1025 of the slave IC 1021 is affected by an external common phase noise 40 induced in the pair of communication lines 1002, 1003, there is a possibility that the power 25 supply circuit 1025 cannot feed a stable DC voltage to the acceleration sensor 1022. As a result, there may arise a difference between the controlled drive voltage outputted from the power supply circuit 1025 and the drive voltage actually received by the acceleration sensor 1022. The difference caused by the common phase noise results in a detection error.

The external common phase noise 40 may be filtered by using a capacitive element such as a capacitor. However, in some cases, the external common phase noise 40 may not fully eliminated by a capacitive element.

According to the second embodiment, as shown in FIG. 6, each of the power supply line 1027 and the ground line 1028 is divided into first, second, and third sections S1-S3. The first section S1 is defined as a section from the output terminals 1021a, 1021b of the slave IC 1021 to the input terminals 1022a, 1022b of the acceleration sensor 1022. The second section S2 is defined as a section from the output terminals 1025a, 1025b of the power supply circuit 1025 to the output terminals 1021a, 1021b of the slave IC 1021. The third section S3 is defined as a section from the output terminals 1021a, 1021b of the slave IC 1021 to the plus and minus terminals 1029a, 1029b of the capacitor 1029.

It is noted that a length of the power supply line 1027 is substantially equal to a length of the ground line 1028 in each of the first, second, and third sections S1-S3. Specifically, a length of the power supply line 1027 connecting the plus output terminal 1021a of the slave IC 1021 to the plus input terminal 1022a of the acceleration sensor 1022 is substantially equal to a length of the ground line 1028 connecting the minus output terminal 1021b of the slave IC 1021 to the minus input terminal 1022b of the acceleration sensor 1022, a length of the power supply line 1027 connecting the plus output terminal 1025a of the power supply circuit 1025 to the plus output terminal 1021a of the slave IC 1021 is substantially equal to a length of the power supply line 1027 connecting the minus output terminal 1025b of the power supply circuit 1025 to the minus output terminal 1021b of the slave IC 1021, and a length of the power supply line 1027 connecting the plus output terminal 1021a of the slave IC 1021 to the plus terminal 1029a of the capacitor 1029 is substantially equal to a length of the power supply line 1027 connecting the minus output terminal 1021b of the slave IC 1021 to the minus terminal 1029b of the capacitor 1029. In such an approach, an impedance of the power supply line 1027 is substantially equal to an impedance of the ground line 1028 in each of the first, second, and third sections S1-S3. Therefore, even if the external common phase noise 1040 is applied to the pair of communication lines 1002, 1003, a phase difference between the power supply line 1027 and the ground line 1028 is reduced so that the power supply circuit 1025 can feed a stable DC voltage to the acceleration sensor 1022. Accordingly, the difference between the controlled drive voltage outputted from the power supply circuit 1025 and the drive voltage actually received by the acceleration sensor 1022 can be reduced. Thus, the acceleration calculated by the sensor controller 1024 can be equal to the acceleration detected by the acceleration sensor 1022.

It is preferable that the length of the power supply line 1027 be substantially equal to the length of the ground line 1028 in each of the first, second, and third sections S1-S3. Alternatively, the length of the power supply line 1027 can be substantially equal to the length of the ground line 1028 in at least one of the first, second, and third sections S1-S3.

### Third Embodiment

A control apparatus 1101 according to a third embodiment of the present invention is described below with reference to FIG. 8.

A difference between the second and third embodiments is as follows. In the second embodiment, the acceleration sensor 1022 is a separate piece of the slave IC 1021. In contrast, in the third embodiment, the acceleration sensor 1022 is incorporated in a slave IC 1121 of a slave node 1120.

According to the third embodiment, as shown in FIG. 8, each of the power supply line 1027 and the ground line 1028 is divided into fourth and fifth sections S4, S5. The fourth section is defined as a section from the output terminals 1025a, 1025b of the power supply circuit 1025 to the input terminals 1022a, 1022b of the acceleration sensor 1022. The fifth section S5 is defined as a section from the output terminals 1025a, 1025b of the power supply circuit 1025 to the plus and minus terminals 1029a, 1029b of the capacitor 1029.

It is noted that a length of the power supply line 1027 is substantially equal to a length of the ground line 1028 in each of the fourth and fifth sections S4, S5. Specifically, a length of the power supply line 1027 connecting the plus output terminal 1025a of the power supply circuit 1025 to the plus input terminal 1022a of the acceleration sensor 1022 is substantially equal to a length of the ground line 1028 connecting the minus output terminal 1025b of the power supply circuit 1025 to the minus input terminal 1022b of the acceleration sensor 1022, and a length of the power supply line 1027 connecting the plus output terminal 1025a of the power supply circuit 1025 to the plus terminal 1029a of the capacitor 1029 is substantially equal to a length of the power supply line 1027 connecting the minus output terminal 1025b of the power supply circuit 1025 to the minus terminal 1029b of the capacitor 1029. In such an approach, an impedance of the power supply line 1027 is substantially equal to an impedance of the ground line 1028 in each of the fourth and fifth sections S4, S5.

Therefore, even if the external common phase noise 1040 is applied to the pair of communication lines 1002, 1003, a phase difference between the power supply line 1027 and the ground line 1028 is reduced so that the power supply circuit 1025 can feed a stable DC voltage to the acceleration sensor 1022. Accordingly, the difference between the controlled drive voltage outputted from the power supply circuit 1025 and the drive voltage actually received by the acceleration sensor 1022 can be reduced. Thus, the acceleration calculated by the sensor controller 1024 can be equal to the acceleration detected by the acceleration sensor 1022.

It is preferable that the length of the power supply line 1027 be substantially equal to the length of the ground line 1028 in each of the fourth and fifth sections S4, S5. Alternatively, the length of the power supply line 1027 can be substantially equal to the length of the ground line 1028 in at least one of the fourth and fifth sections S4, S5.

(Modification)

The embodiments described above can be modified in various ways. For example, a sensor other than an acceleration sensor can be used as a slave. For example, a contact sensor or a distance sensor can be used as a slave.

According to the embodiments, the impedance of the power supply line 1027 is matched to the impedance of the ground line 1028 by equalizing the length of the power supply line 1027 to the length of the ground line 1028. Alternatively, the impedance of the power supply line 1027 can be matched to the impedance of the ground line 1028 by adjusting other parameters such as shapes and materials of the power supply line 1027 and the ground line 1028.

According to the embodiments, the master node 1010 and the slave node 1020 perform differential communication through the pair of communication lines 1002, 1003. The present invention can be applied to a case where the master node 1010 and the slave node 1020 perform differential communication through three or more communication lines.

Such changes and modifications are to be understood as being within the scope of the present invention as defined by the appended claims.

What is claimed is:

1. An electronic apparatus comprising:
an integrated circuit having a first terminal connected to a power supply line or a signal line;
a capacitor having first and second ends and configured to eliminate noise on the power supply line or the signal line;
a first wire having a first length and connecting the first end of the capacitor to the first terminal; and
a second wire having a second length and connecting the second end of the capacitor to a reference potential, wherein
the first length is substantially equal to the second length.

2. The electronic apparatus of claim 1, wherein
the integrated circuit further has a second terminal connected to the reference potential, and
the second wire connects the second end of the capacitor to the second terminal of the integrated circuit.

3. The electronic apparatus of claim 2, wherein
the first terminal of the integrated circuit is located adjacent to the second terminal of the integrated circuit.

4. The electronic apparatus of claim 1, further comprising:
a sensor configured to detect information related to a collision of a vehicle, wherein
the integrated circuit transmits the information to a control apparatus that controls an occupant protection device.

5. A differential communication apparatus comprising:
a master integrated circuit;
a slave integrated circuit connected to the master integrated circuit through a pair of communication lines to perform differential communication with the master integrated circuit, the slave integrated circuit including a power supply circuit fed with a first voltage from the master integrated circuit through the pair of communication lines;
a sensor device connected to the power supply circuit through a power supply line and a ground line and fed with a second voltage from the slave integrated circuit, the sensor device being configured to output a third voltage depending on the second voltage to the slave integrated circuit, the sensor device being a separate piece of the slave integrated circuit; and
a capacitive element connected between the power supply line and the ground line, wherein
each of the power supply line and the ground line includes a first section connecting an output terminal of the slave integrated circuit to an input terminal of the sensor device, a second section connecting an output terminal of the power supply circuit to the output terminal of the slave integrated circuit, and a third section connecting a terminal of the capacitive element to the output terminal of the slave integrated circuit, and
an impedance of the power supply line is substantially equal to an impedance of the ground line in at least one of the first, second, and third sections.

6. The differential communication apparatus of claim 5, wherein,
a length of the power supply line is substantially equal to a length of the ground line in the at least one of the first, second, and third sections.

7. A differential communication apparatus comprising:
a master integrated circuit;
a slave integrated circuit including an input/output circuit connected to the master integrated circuit through a pair of communication lines to perform differential communication with the master integrated circuit, a power supply circuit fed with a first voltage from the master integrated circuit through the input/output circuit, and a sensor device connected to the power supply circuit through a power supply line and a ground line and fed with a second voltage from the power supply circuit, the sensor device being configured to output a third voltage depending on the second voltage to the input/output circuit; and
a capacitive element connected between the power supply line and the ground line, wherein
each of the power supply line and the ground line includes a first section connecting an output terminal of the power supply circuit to an input terminal of the sensor device, and a second section connecting a terminal of the capacitive element to the output terminal of the power supply circuit, and
an impedance of the power supply line is substantially equal to an impedance of the ground line in at least one of the first and second sections.

8. The differential communication apparatus of claim 7, wherein,
a length of the power supply line is substantially equal to a length of the ground line in the at least one of the first and second sections.
